(19) United States
(12) Patent Application Publication
(10) Pub. No.: US 2025/0275087 A1
(43) Pub. Date: Aug. 28, 2025

(54) ELECTRONIC DEVICE AND LIQUID-COOLED CABINET

(71) Applicant: xFusion Digital Technologies Co., Ltd, Zhengzhou City (CN)

(72) Inventor: Chenglong Wang, Zhengzhou (CN)

(73) Assignee: xFusion Digital Technologies Co., Ltd, Zhengzhou City (CN)

(21) Appl. No.: 19/207,669

(22) Filed: May 14, 2025

Related U.S. Application Data
(63) Continuation of application No. PCT/CN2023/117668, filed on Sep. 8, 2023.

(30) Foreign Application Priority Data
Nov. 14, 2022 (CN) 202211422580.4

(51) Int. Cl. H05K 7/20; H05K 7/14

(52) U.S. Cl. CPC H05K 7/20236; H05K 7/1488; H05K 7/20772

(57) ABSTRACT

Provided in this disclosure are an electronic device and a liquid-cooled cabinet. The electronic device includes a housing and an indication module. The housing is provided with an accommodation cavity and a mounting slot. The mounting slot is in communication with the accommodation cavity and the exterior of the housing. The accommodation cavity is configured to accommodate a cooling medium. The indication module includes an indicator light and a sealing assembly. The indicator light and the sealing assembly are mounted in the mounting slot. The sealing assembly is located on a side of the indicator light facing away from the accommodation cavity and seals the mounting slot. The sealing assembly includes a light-transmitting portion, and the light emitted by the indicator light can pass through the light-transmitting portion to reach the exterior of the housing.

### CROSS REFERENCE TO RELATED APPLICATIONS

This application is a continuation of International Application No. PCT/CN2023/117668, filed on Sep. 8, 2023, which claims priority to Chinese Patent Application No. 202211422580.4, filed on Nov. 14, 2022. The disclosures of the aforementioned applications are hereby incorporated by reference in their entireties.

### TECHNICAL FIELD

The present application relates to electronic devices, and in particular to an electronic device and a liquid-cooled cabinet.

### BACKGROUND

In order to improve power usage effectiveness (PUE) metrics of data centers, a liquid cooling method is generally used to perform full-immersion heat dissipation on electronic components inside electronic devices, thus eliminating the need for any fans. The liquid cooling method is an optimal solution for improving the PUE metrics. However, when a liquid is used for colling, the housing of the electronic devices shall be sealed, and the operating statuses of the electronic components inside the electronic devices can not be determined.

### SUMMARY

Embodiments of the present application aim to provide an electronic device and a liquid-cooled cabinet. The electronic device uses liquid to dissipate heat, while the operating status of the electronic device can be also ascertained.

Embodiments of the present application provide an electronic device. The electronic device includes a housing and an indication module. The housing is provided with an accommodation cavity and a mounting slot. The mounting slot is in communication with the accommodation cavity and the exterior of the housing. The accommodation cavity is configured to accommodate a cooling medium. The indication module includes an indicator light and a sealing assembly, and the indicator light and the sealing assembly are mounted in the mounting slot. The sealing assembly is located on the side of the indicator light facing away from the accommodation cavity and seals the mounting slot. The sealing assembly includes a light-transmitting portion, and the light emitted by the indicator light is capable of passing through the light-transmitting portion to reach the exterior of the housing.

In the electronic device provided in some embodiments of the present application, the light emitted by the indicator light in the indication module can pass through the light-transmitting portion of the sealing assembly to reach the exterior of the housing, allowing a user to ascertain the operating status of the electronic device by observing light variations. In addition, the sealing assembly in the indication module can seal the mounting slot, so that the indication module also seals the housing. This prevents the cooling medium inside the accommodation cavity of the housing from flowing out of the mounting slot, ensuring the sealing performance of the housing and facilitating liquid-cooling heat dissipation for the electronic device.

In an embodiment, the mounting slot includes a first portion and a second portion. An opening of the first portion is located on an outer surface of the housing, the second portion is in communication with the first portion and the accommodation cavity, and the indicator light is mounted in the second portion. The sealing assembly is mounted in the first portion and seals the first portion. By mounting the sealing assembly of the indication module in the first portion and the indicator light of the indication module in the second portion, the indication module achieves a compact dimension in a thickness direction. The design effectively meets the dimensional requirements of the electronic device for sealing the indication module.

In an embodiment, an aperture diameter of the first portion is greater than an aperture diameter of the second portion. Thus, a path for the cooling medium to flow through the first portion and the second portion is relatively long. This makes the cooling medium not so quickly flow out of the mounting slot, thereby improving a sealing effect of the indication module on the housing.

In an embodiment, the sealing assembly includes a first sealing member, a light-transmitting member, and a fixing member. The first sealing member is clamped between the light-transmitting member and a slot bottom wall of the first portion. The fixing member is fixedly connected to a slot side wall of the first portion, and abuts against a surface of the light-transmitting member facing away from the first sealing member. The fixing member is fixedly connected to the slot side wall of the first portion, so that the light-transmitting member generates sufficient pressure on the first sealing member, thereby achieving a sealing effect of the sealing assembly on the housing, and further achieving the sealing effect of the indication module on the housing.

In an embodiment, the first sealing member is provided with a through-hole. The through-hole of the first sealing member extends through the first sealing member in a thickness direction of the first sealing member. At least a portion of the through-hole of the first sealing member is arranged opposite to the second portion. The light-transmitting member includes a light-transmitting section, at least a portion of the light-transmitting section is arranged opposite to the through-hole, the fixing member is provided with a light-transmitting hole, the light-transmitting hole extends through the fixing member in a thickness direction of the fixing member, at least a portion of the light-transmitting hole is arranged opposite to the light-transmitting section and exposes the light-transmitting section, and the light-transmitting portion includes the through-hole of the first sealing member, the light-transmitting section, and the light-transmitting hole. The light emitted by the indicator light can sequentially pass through the through-hole of the first sealing member, the light-transmitting section, and the light-transmitting hole, and reach the exterior of the housing. This allows the user to observe the light emitted by the indicator light through the sealing assembly and ascertain the operating status of the electronic device based on the observed light variations.

In an embodiment, the light-transmitting hole is one of a hexagonal hole, a circular hole with a linear slot, a circular hole with a cross-shaped slot, or a circular hole with a fastening tool bayonet. This facilitates insertion of a conventional fastening tool into the light-transmitting hole to rotate the fixing member, thereby helping achieve a fixed connection between the fixing member and the slot side wall of the first portion or achieve a removal of the fixing member from the first portion.

In an embodiment, the slot side wall of the first portion is provided with a first thread, an outer peripheral surface of the fixing member is provided with a second thread, and the second thread engages with the first thread. By providing the first thread on the slot side wall of the first portion, the flow path length of the cooling medium in the first portion is increased, thereby further enhancing the sealing effect of the sealing assembly.

In an embodiment, the sealing assembly further includes a second sealing member. The second sealing member is clamped between the light-transmitting member and the fixing member, the second sealing member is provided with a through-hole, the through-hole of the second sealing member extends through the second sealing member in a thickness direction of the second sealing member, and at least a portion of the through-hole of the second sealing member is arranged opposite to the light-transmitting section and the light-transmitting hole to expose the light-transmitting section. By providing the second sealing member, the sealing effect of the sealing assembly on the housing is further enhanced while light transmission is ensured, thereby further improving the sealing effect of the indication module on the housing.

In an embodiment, the housing includes a rear panel and a front panel that are oppositely arranged. The housing is provided with a liquid inlet and a liquid outlet. The liquid inlet and the liquid outlet are disposed in the rear panel, and extend through the rear panel in a thickness direction of the rear panel. The front panel is provided with the mounting slot, and the mounting slot extends through the front panel in a thickness direction of the front panel. The liquid inlet and liquid outlet are provided on the rear panel, and the indication module is provided on the front panel, which facilitates the cooling medium to circulate into the accommodation cavity from a rear side of the electronic device and facilitates observation of the operating status of the electronic device from a front side of the electronic device, thereby facilitating the ease of use by a user.

In an embodiment, there are a plurality of mounting slots and indication modules, and each indication module is mounted in one of the mounting slots.

The embodiments of the present application also provide a liquid-cooled cabinet, including a cabinet body and the at least one electronic device as described above, and each of the at least one electronic device is mounted on the inner side of the cabinet body.

In an embodiment, the liquid-cooling cabinet further includes a main liquid inlet pipeline, a main liquid outlet pipeline, a plurality of liquid inlet pipes, and a plurality of liquid outlet pipes, each liquid inlet pipe connects the main liquid inlet pipeline with a liquid inlet of the electronic device, and each liquid outlet pipe connects the main liquid outlet pipeline with a liquid outlet of the electronic device.

In an embodiment, the liquid-cooled cabinet further includes a coolant distribution unit. The coolant distribution unit is connected to the main liquid inlet pipeline and the main liquid outlet pipeline, and is configured to deliver a cooling medium to the main liquid inlet pipeline and receive the cooling medium delivered by the main liquid outlet pipeline.

### BRIEF DESCRIPTION OF DRAWINGS

In order to more clearly illustrate technical solutions in embodiments of the present application or in the related art, the accompany drawings to be used in the embodiments of the present application or in the related art will be described briefly. Apparently, the drawings in the following description are only some embodiments of the present application, and other drawings may be obtained based on these drawings without creative effort for those skilled in the art.

FIG. 1 is a structural diagram illustrating a liquid-cooled cabinet according to an embodiment of the present application;

FIG. 2 is a structural diagram illustrating an electronic device in the liquid-cooled cabinet shown in FIG. 1;

FIG. 3 is a structural diagram illustrating the electronic device shown in FIG. 2 from another perspective;

FIG. 4 is a partial cross-sectional view illustrating the electronic device shown in FIG. 3;

FIG. 5 is a partial cross-sectional view illustrating a housing in the electronic device shown in FIG. 4;

FIG. 6 is a partial structural diagram illustrating the electronic device shown in FIG. 3;

FIG. 7 is a structural diagram illustrating a partial structure of the electronic device shown in FIG. 3 from another perspective;

FIG. 8 is a structural diagram illustrating a fixing member in the partial structure of the electronic device shown in FIG. 7; and

FIG. 9 is a structural diagram illustrating fixing members with different light-transmitting holes in other embodiments.

### DESCRIPTION OF EMBODIMENTS

The following describes technical solutions in embodiments of the present application in combination with accompanying drawings of the embodiments of the present application. It is noted that the described embodiments are some but not all of the available/possible embodiments of the present application. All other embodiments obtained by those skilled in the art without creative efforts based on the embodiments described in the present application fall within the protection scope of the present application.

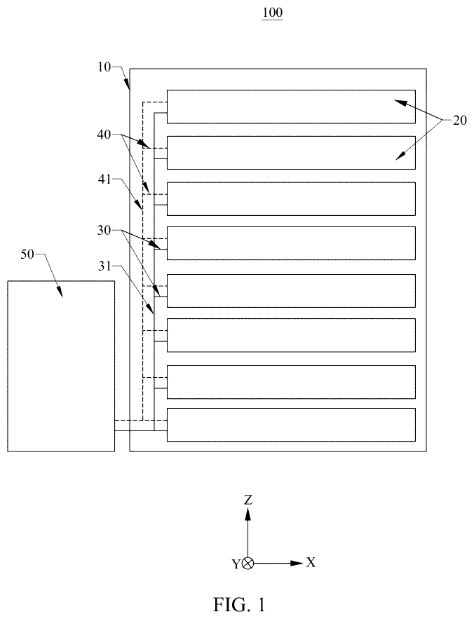

As shown in FIG. 1, FIG. 1 is a structural diagram illustrating a liquid-cooled cabinet 100 according to an embodiment of the present application.

For convenience of description, a length direction of the liquid-cooled cabinet 100 shown in FIG. 1 is defined as an X-axis direction, a width direction as a Y-axis direction, and a height direction as a Z-axis direction. The orientation terms, such as “front” and “rear” used in the description of the liquid-cooled cabinet 100 in the embodiments of the present application, are based on the orientation shown in FIG. 1 of the description, where the positive X-axis direction is defined as the “front” and the negative X-axis direction as the “rear”. These terms do not limit actual application scenarios of the liquid-cooled cabinet 100.

The liquid-cooled cabinet 100 includes a cabinet body 10, a plurality of electronic devices 20, a plurality of liquid inlet pipes 30 (shown as dashed lines in FIG. 1) and a plurality of liquid outlet pipes 40, a main liquid inlet pipeline 31, a main liquid outlet pipeline 41, and a coolant distribution unit (CDU) 50. Each electronic device 20 is mounted on an inner side of the cabinet body 10. Each liquid inlet pipe 30 connects the main liquid inlet pipeline 31 with a liquid inlet of each electronic device 20, and each liquid outlet pipe 40 connects the main liquid outlet pipeline 41 with a liquid outlet of each electronic device 20. The coolant distribution unit (CDU) 50 is connected to the main liquid inlet pipeline 31 and the main liquid outlet pipeline 41. The coolant distribution unit 50 is configured to deliver a cooling medium to the main liquid inlet pipeline 31 and to receive the cooling medium delivered by the main liquid outlet pipeline 41, thus enabling circulation of the cooling medium between the coolant distribution unit 50 and the electronic devices 20, and achieving continuous liquid-cooling heat dissipation for the electronic devices 20. In the embodiment shown in FIG. 1, the coolant distribution unit 50 is located outside the cabinet body 10. In other embodiments, the coolant distribution unit 50 may also be located on the inner side of the cabinet body 10, which is not limited in the present application.

The electronic devices 20 may be servers, computers, switches, etc. In some embodiments of the present application, the electronic devices 20 are described by using servers as examples. The cooling medium may be a fluid with a cooling function, such as coolant or cooling gas. It should be noted that liquid cooling methods include single-phase immersion liquid cooling and two-phase immersion liquid cooling. Single-phase immersion liquid cooling may adopt a cooling medium with a higher boiling point. For example, the cooling medium may be fluorinated fluid, mineral oil, synthetic oil, natural oil, etc. Two-phase immersion liquid cooling may adopt a cooling medium with a low boiling point. For example, the cooling medium may be silicate esters, aromatic compounds, organosilicon, etc.

Specifically, during operation of the liquid-cooled cabinet 100, the coolant distribution unit 50 delivers the cooling medium to the main liquid inlet pipeline 31, and distributes the cooling medium to each electronic device 20 via the plurality of liquid inlet pipes 30. The cooling medium is delivered to the interior of the electronic devices 20 through the liquid inlets of the electronic devices 20 and takes away heat from the electronic devices 20 to perform liquid-cooling heat dissipation on the electronic devices 20. The heat-bearing cooling medium flows out of the electronic devices 20 through liquid outlets. The heat-bearing cooling medium is delivered to the coolant distribution unit 50 through the liquid outlet pipes 40 and the main liquid outlet pipeline 41, and is cooled in the coolant distribution unit 50. The cooled cooling medium is delivered through the main liquid inlet pipeline 31 and distributed to the interior of each electronic device 20 via the plurality of inlet pipes 30, enabling circulation of the cooling medium between the electronic devices 20 and the coolant distribution unit 50, thus achieving continuous liquid-cooling heat dissipation for the electronic devices 20.

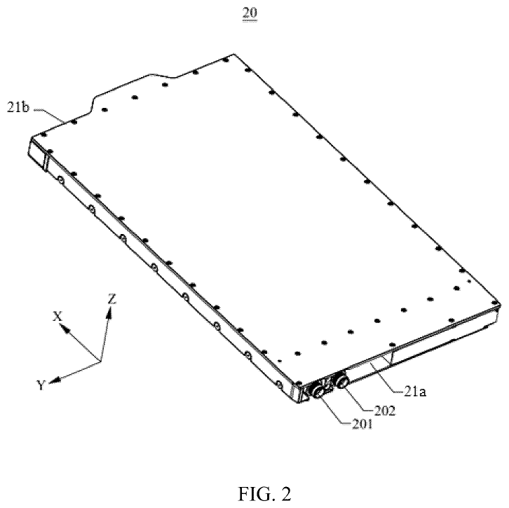

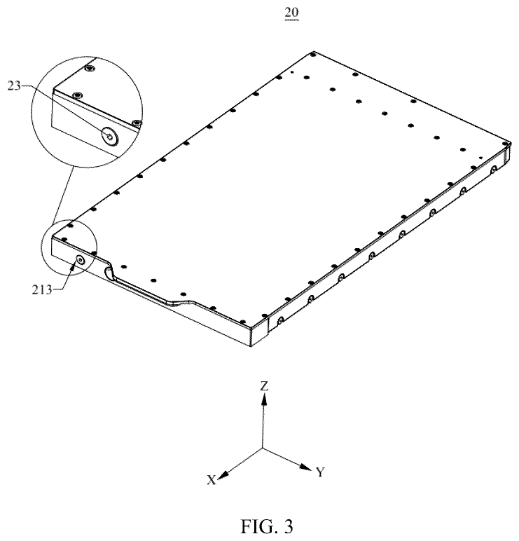

As shown in FIGS. 2 and 3, FIG. 2 is a structural diagram illustrating an electronic device 20 in the liquid-cooled cabinet 100 shown in FIG. 1, and FIG. 3 is a schematic diagram illustrating the electronic device 20 shown in FIG. 2 from another perspective.

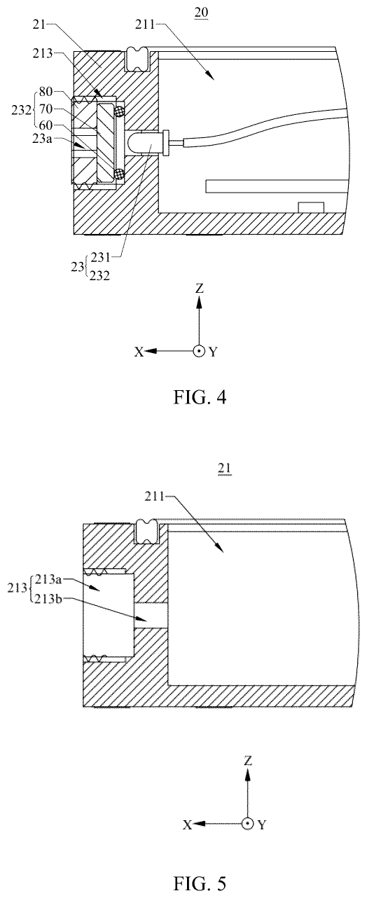

Each electronic device 20 includes a housing 21 (as shown in FIG. 4), an electronic component (not shown in FIGS. 2 and 3), and an indication module 23. The electronic component is mounted inside the housing 21, and the indication module 23 is mounted on the housing 21. The electronic component may be a circuit board, chip, memory module, drive or other components. The indication module 23 is configured to emit light to indicate an operating status of the electronic component inside the housing 21, thereby facilitating observation of the operating status of the electronic device 20. Additionally, the indication module 23 is configured to seal the housing 21 to prevent the cooling medium inside the housing 21 from flowing out. There is at least one indication module 23, such as one, two, four, etc. The number of indication modules 23 can be set based on actual requirements, which is not limited in the present application.

Specifically, the housing 21 is provided with an accommodation cavity 211 (as shown in FIG. 4), and the accommodation cavity 211 is configured to accommodate the electronic component and the cooling medium. The housing 21 is provided with a liquid inlet 201 (see FIG. 2), a liquid outlet 202 (see FIG. 2), and a mounting slot 213 (see FIG. 4). The liquid inlet 201, the liquid outlet 202, and the mounting slot 213 all extend through the housing 21 along a thickness direction of the housing 21 and are in communication with the accommodation cavity 211 of the housing 21 and the exterior of the housing 21. The liquid inlet 201 is configured to deliver the cooling medium to the accommodation cavity 211, and the liquid outlet 202 is configured to discharge the cooling medium from the accommodation cavity 211, thereby enabling circulation of the cooling medium between the interior and exterior of the electronic device 20 to achieve continuous heat dissipation on the electronic device 20. At least one mounting slot 213 is provided, and each mounting slot 213 is configured to mount one indication module 23.

As shown in FIG. 2, the housing 21 includes a rear panel 21a and a front panel 21b, which are oppositely arranged. The liquid inlet 201 and the liquid outlet 202 are provided in the rear panel 21a. The liquid inlet 201 and the liquid outlet 202 extend through the rear panel 21a in a thickness direction of the rear panel 21a to establish communication between the accommodation cavity 211 of the housing 21 and the exterior of the housing 21. The front panel 21b is provided with the mounting slot 213. The mounting slot 213 extends through the front panel 21b in a thickness direction of the front panel 21b to establish communication between the accommodation cavity 211 of the housing 21 and the exterior of the housing 21. As shown in FIG. 4, the mounting slot 213 is provided on the front panel 21b, which allows the indication module 23 to be located at the front of the electronic device 20, thereby facilitating observation of the operating status of the electronic device 20 from the front of the cabinet body 10. It is understandable that in other embodiments, the mounting slot 213 may also be provided at other positions of the housing 21, such as on a side panel of the housing 21. The specific position of the mounting slot 213 is not limited in the present application.

In combination with FIG. 4 and FIG. 5, FIG. 4 is a partial cross-sectional view illustrating the electronic device 20 shown in FIG. 3, and FIG. 5 is a partial cross-sectional view illustrating the housing 21 in the electronic device 20 shown in FIG. 4.

The mounting slot 213 includes a first portion 213a and a second portion 213b, and an aperture diameter of the first portion 213a is greater than an aperture diameter of the second portion 213b. Specifically, an opening of the first portion 213a is located on an outer surface of the housing 21 facing away from the accommodation cavity 211, and the first portion 213a is recessed from the outer surface of the housing 21 toward the accommodation cavity 211. A first thread is provided on a slot side wall of the first portion 213a. An opening of the second portion 213b is located on a slot bottom wall of the first portion 213a, and is in communication with the first portion 213a and the accommodation cavity 211. For example, the first portion 213a and the second portion 213b are cylindrical and coaxial.

The indication module 23 includes an indicator assembly 231 and a sealing assembly 232. Both the indicator assembly 231 and the sealing assembly 232 are mounted in the mounting slot 213. The indicator assembly 231 is mounted in the second portion 213b and configured to emit light. The sealing assembly 232 is mounted in the first portion 213a and configured to seal the first portion 213a, thereby enabling sealing of the mounting slot 213 by the indication module 23, and realizing sealing of the housing 21 by the indication module 23. The sealing assembly 232 includes a light-transmitting portion 23a. The light-transmitting portion 23a is configured to transmit light emitted by the indicator assembly 231, allowing the light to pass through the light-transmitting portion 23a to the exterior of the housing 21.

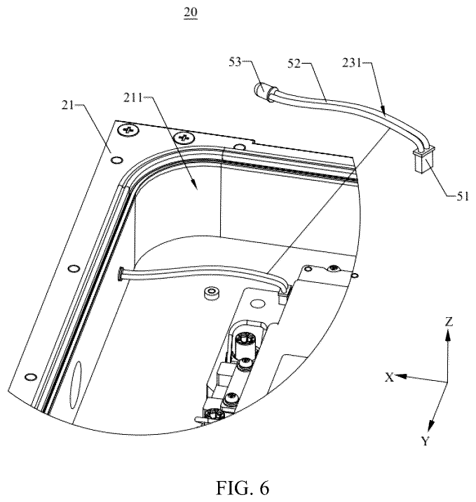

In combination with FIG. 4 and FIG. 6, FIG. 6 is a partial structural diagram illustrating the electronic device 20 shown in FIG. 3.

The indicator assembly 231 includes a cable connector 51, a connection cable 52, and an indicator light 53. The connection cable 52 is electrically connected between the cable connector 51 and the indicator light 53. The cable connector 51 is electrically connected to an electronic component (such as a circuit board) inside the housing 21. The cable connector 51 can transmit an electrical signal via the connection cable 52 to the indicator light 53. The indicator light 53 can emit light based on the operation of the electrical signal. For example, the cable connector 51 can be plugged into a circuit board. The indicator light 53 is mounted in the second portion 213b and is configured to emit light toward the first portion 213a, allowing the light emitted by the indicator light 53 to propagate from the second portion 213b into the first portion 213a. Variations in the light emitted by the indicator light 53 can indicate the operating status of the components inside the housing 21, allowing a user to ascertain the operating status of the electronic device 20 by observing these light variations. “Light variations” include presence or absence of light, changes in light intensity, or changes in light color, etc.

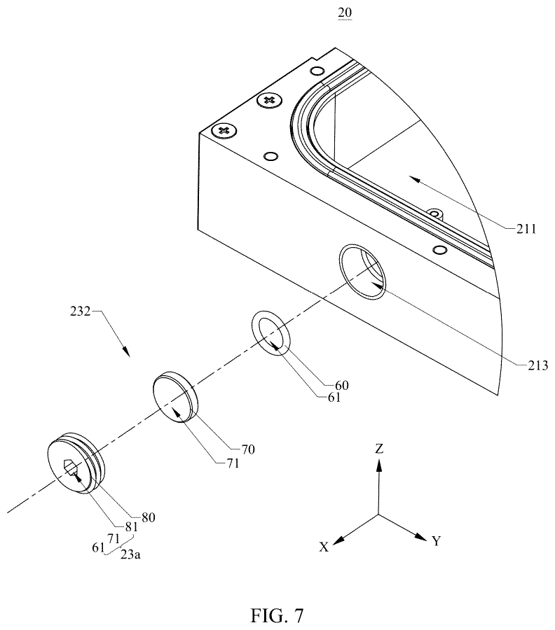

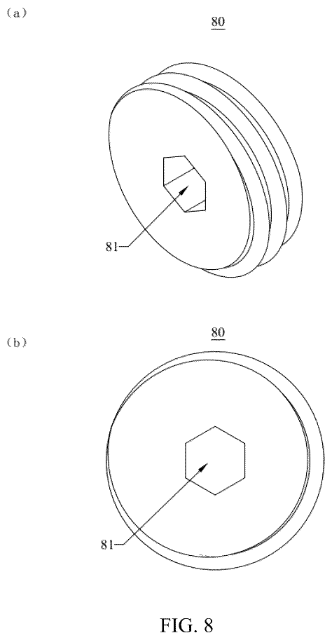

In combination with FIG. 4 and FIG. 7, FIG. 7 is a structural diagram illustrating a partial structure of the electronic device 20 shown in FIG. 3 from a different perspective.

The sealing assembly 232 includes a first sealing member 60, a light-transmitting member 70, and a fixing member 80. The first sealing member 60, the light-transmitting member 70, and the fixing member 80 are mounted in the first portion 213a.

Specifically, the first sealing member 60 is clamped between the slot bottom wall of the first portion 213a and the light-transmitting member 70. The first sealing member 60 is provided with a through-hole 61. The through-hole 61 extends through the first sealing member 60 in a thickness direction of the first sealing member 60. The through-hole 61 is in communication with the second portion 213b, and is configured opposite to the second portion 213b, thereby enabling the light emitted by the indicator light 53 located in the second portion 213b to transmit through the through-hole 61. This allows the first sealing member 60 to transmit the light emitted by the indicator light 53. For example, the first sealing member 60 is a rubber sealing ring. The through-hole 61 is a circular hole, and the through-hole 61 is coaxial with the second portion 213b. In some other embodiments, a portion of the through-hole 61 may be arranged opposite to the second portion 213b. The phrase “A is arranged opposite to B” means that the projection of A on B at least partially overlaps B.

The light-transmitting member 70 is located on a side of the first sealing member 60 facing away from the indicator light 53. For example, the light-transmitting member 70 is made of a light-transmitting material. For example, the light-transmitting member 70 is a glass panel. The light-transmitting member 70 is provided with a light-transmitting section 71. The light-transmitting section 71 is arranged opposite to the through-hole 61, so that the light passing through the through-hole 61 can pass through the light-transmitting section 71. For example, the light-transmitting section 71 is coaxial with the through-hole 61. In some other embodiments, a portion of the light-transmitting section 71 may be arranged opposite to the through-hole 61.

The fixing member 80 is fixedly connected to the slot side wall of the first portion 213a, and abuts against a surface of the light-transmitting member 70 facing away from the first sealing member 60. Specifically, a second thread is provided on an outer peripheral surface of the fixing member 80. The second thread engages with the first thread on a slot inner wall of the first portion 213a. This provides a fixed connection between the fixing member 80 and the slot side wall of the first portion 213a, thereby implementing a fixed connection between the sealing assembly 232 and the housing 21. A surface of the fixing member 80 facing away from the light-transmitting member 70 is flush with the outer surface of the housing 21 facing away from the accommodation cavity 211, or is recessed relative to the outer surface of the housing 21 facing away from the accommodation cavity 211. That is, the outer surface of the fixing member 80 does not protrude beyond the outer surface of the housing 21, thereby utilizing thickness space of the housing 21. The fixing member 80 is provided with a light-transmitting hole 81, and the light-transmitting hole 81 extends through the fixing member 80 in a thickness direction of the fixing member 80. The light-transmitting hole 81 is arranged opposite to the light-transmitting section 71 and exposes the light-transmitting section 71, so that the light passing through the light-transmitting section 71 can pass through the light-transmitting hole 81. For example, the light-transmitting hole 81 is coaxial with the light-transmitting section 71. In some other embodiments, a portion of the light-transmitting hole 81 may be arranged opposite to the light-transmitting section 71.

After mounting the sealing assembly 232, the fixing member 80 is fixedly connected to the slot side wall of the first portion 213a, and abuts against the surface of the light-transmitting member 70 facing away from the first sealing member 60, thereby clamping the first sealing member 60 between the light-transmitting member 70 and the slot bottom wall of the first portion 213a. This allows the sealing assembly 232 to seal the first portion 213a. Consequently, the indication module 23 seals the housing 21, preventing the cooling medium inside the accommodation cavity 211 of the housing 21 from leaking from the mounting slot 213. In addition, by providing the first thread on the slot side wall of the first portion 213a, the flow path length of the cooling medium in the first portion 213a is increased, thereby further enhancing a sealing effect of the sealing assembly 232.

The through-hole 61 of the first sealing member 60, the light-transmitting section 71 of the light-transmitting member 70, and the light-transmitting hole 81 of the fixing member 80 collectively form the light-transmitting portion 23a of the sealing assembly 232. This configuration allows the light emitted by the indicator light 53 to sequentially pass through the through-hole 61, the light-transmitting section 71, and the light-transmitting hole 81, before reaching the exterior of the housing 21, thereby enabling the user to observe the light emitted by the indicator assembly 231 through the sealing assembly 232, and ascertain the operating status of the electronic device 20 based on the observed light variations.

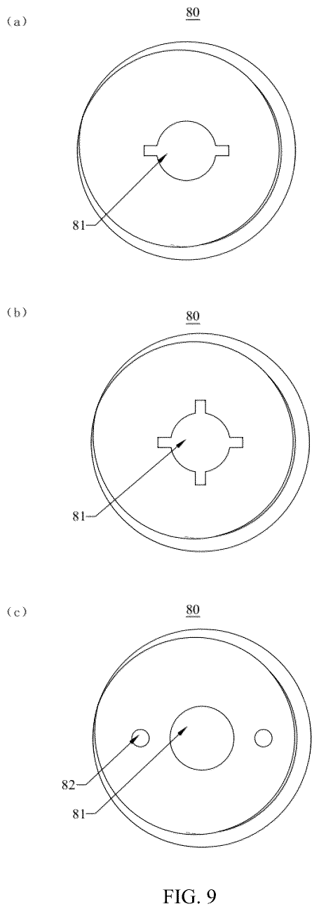

In combination with FIG. 4 and FIG. 8, FIG. 8 is a structural diagram illustrating the fixing member 80 in the partial structure of the electronic device 20 shown in FIG. 7. FIG. 8 (a) is a perspective structural schematic diagram of the fixing member 80 from a specific perspective, and FIG. 8 (b) is a front view of the fixing member 80.

In FIG. 8, the fixing member 80 is a fastening stud. The light-transmitting hole 81 combines light transmitting and fastening functions, eliminating the need for an additional slot for a fastening tool on the fixing member 80. The fastening tool can be inserted into the light-transmitting hole 81, and can rotate the fixing member 80 relative to the first portion 213a, thereby providing a fixed connection between the fixing member 80 and the slot side wall of the first portion 213a or allowing a removal of the fixing member 80 from the first portion 213a.

In the embodiment shown in FIG. 8, the light-transmitting hole 81 is a hexagonal hole. The fastening tool can be inserted into the light-transmitting hole 81 to tighten the fixing member 80, thereby securing the fixing member 80 to the housing 21. As shown in FIG. 9, FIG. 9 is a structural diagram of fixing members 80 with different light-transmitting holes 81 in a plurality of embodiments. In FIG. 9, the light-transmitting hole 81 of the fixing member 80 may be in various forms. For example, the light-transmitting hole 81 may be a circular hole with a linear slot (as shown in of FIG. 9 (a)), a circular hole with a cross-shaped slot (as shown in of FIG. 9 (b)), a circular hole with fastening tool bayonets 82 on both sides (as shown in of FIG. 9 (c)), etc.

As shown in FIG. 4, when the sealing assembly 232 is mounted, the first sealing member 60, the light-transmitting member 70, and the fixing member 80 are sequentially placed into the first portion 213a. The fastening tool is then inserted into the light-transmitting hole 81 of the fixing member 80 to fixedly connect the fixing member 80 to the slot side wall of the first portion 213a. The fixing member 80 abuts against the surface of the light-transmitting member 70 facing away from the first sealing member 60, so that the fixing member 80 is clamped between the light-transmitting member 70 and the slot bottom wall of the first portion 213a. This enables the sealing assembly 232 to seal the first portion 213a. Consequently, the indication module 23 seals the housing 21, preventing the cooling medium inside the accommodation cavity 211 of the housing 21 from leaking out of the mounting slot 213. In some embodiments of the present application, the fixing member 80 is fixedly connected to the slot side wall of the first portion 213a, so that the light-transmitting member 70 generates sufficient pressure on the first sealing member 60, thereby creating the sealing effect of the sealing assembly 232 on the housing 21 to accomplish the sealing effect of the indication module 23 on the housing 21.

The indication module 23 in some embodiments of the present application exhibits reliable sealing performance. By mounting the sealing assembly 232 of the indication module 23 in the first portion 213a and the indicator light 53 of the indicator assembly 231 in the second portion 213b, the indication module 23 achieves a compact design in a thickness direction. The design effectively meets the dimensional requirements of the electronic device 20 for sealing the indication module 23. In addition, the aperture diameter of the first portion 213a is greater than the aperture diameter of the second portion 213b. Thus, the path for the cooling medium to flow through the first portion 213a and the second portion 213b is relatively long. This makes the cooling medium difficult to flow out of the mounting slot 213, thereby improving the sealing effect of the indication module 23 on the housing 21.

In some embodiments, a second sealing member may be additionally provided between the light-transmitting member 70 and the fixing member 80, to further enhance the sealing effect of the sealing assembly 232 on the housing 21, thereby further enhancing the sealing effect of the indication module 23 on the housing 21. The second sealing member is provided with a through-hole, and the through-hole of the second sealing member extends through the second sealing member in a thickness direction of the second sealing member. The through-hole of the second sealing member is arranged opposite to the light-transmitting section 71 and the light-transmitting hole 81, and exposes the light-transmitting section 71. In this case, the light emitted by the indicator assembly 231 enters the first portion 213a from the second portion 213b, and sequentially passes through the through-hole 61 of the first sealing member 60, the light-transmitting section 71 of the light-transmitting member 70, the through-hole of the second sealing member, and the light-transmitting hole 81 of the fixing member 80. For example, the second sealing member has a same structure as the first sealing member 60, and the second sealing member and the first sealing member 60 both are rubber sealing rings. In other embodiments, a portion of the though-hole of the second sealing member may be arranged opposite to the light-transmitting section 71 and the light-transmitting hole 81.

As shown in FIG. 1, when the liquid-cooled cabinet 100 is assembled, the electronic device 20 is mounted inside the cabinet body 10 from a front side of the cabinet body 10. The rear panel 21a of the electronic device 20 faces away from a front side opening of the cabinet body 10, and the front panel 21b faces toward the front opening of the cabinet body 10. The liquid inlet 201 located on a rear side of the electronic device 20 connects with the liquid inlet pipe 30, and the liquid outlet 202 connects with the liquid outlet pipe 40. The cooling medium delivered from the liquid inlet pipe 30 is introduced into the accommodation cavity 211 of the electronic device 20 through the liquid inlet 201 to perform liquid-cooling heat dissipation on the electronic components mounted in the accommodation cavity 211. The heat-bearing cooling medium is discharged from the liquid outlet 202 either in liquid form (when single-phase immersion liquid cooling is used) or as a liquid-gas mixture (when two-phase immersion liquid cooling is used). The indicator assembly 231 in the indication module 23 on a front side of the electronic device 20 can emit light. The sealing assembly 232 seals the housing 21 of the electronic device 20 to prevent the cooling medium from flowing out of the mounting slot 213. At the same time, the sealing assembly 232 can transmit the light emitted by the indicator assembly 231, allowing the users to observe the light and ascertain the operating status of the electronic device 20 based on light variations. The sealing assembly 232 in the embodiments of the present application achieves sealing and light-transmitting functions, effectively preventing the cooling medium from leaking and ensuring sealing performance inside the electronic device 20 and external light transmitting effect of the indication module 23.

In addition, in an embodiment, the liquid inlet 201 and the liquid outlet 202 are provided on the rear panel 21a and the indication module 23 is provided on the front panel 21b, which facilitates the cooling medium to circulate into the accommodation cavity 211 from the rear side of the electronic device 20 and allows the operating status of the electronic device 20 to be observed from the front side of the electronic device 20, thereby facilitating the user to operate and maintain the device.

The above disclosure represents merely preferred embodiments of the present application, and should not be construed as a limitation of the scope of the present application. Those skilled in the art can understand and implement all or part of the processes of the above embodiments, and any equivalent changes made based on claims of the present application still fall within the scope covered by the present application.

What is claimed is:

1. An electronic device, comprising a housing and an indication module, wherein the housing is provided with an accommodation cavity and a mounting slot, the mounting slot is in communication with the accommodation cavity and the exterior of the housing, the accommodation cavity is configured to accommodate a cooling medium, the indication module comprises an indicator light and a sealing assembly that are mounted in the mounting slot, the sealing assembly is located on a side of the indicator light facing away from the accommodation cavity and seals the mounting slot, the sealing assembly comprises a light-transmitting portion, and light emitted by the indicator light passes through the light-transmitting portion to reach the exterior of the housing.

2. The electronic device according to claim 1, wherein the mounting slot comprises a first portion and a second portion, an opening of the first portion is located on an outer surface of the housing, the second portion is in communication with the first portion and the accommodation cavity, the indicator light is mounted in the second portion, and the sealing assembly is mounted in the first portion and seals the first portion.

3. The electronic device according to claim 2, wherein an aperture diameter of the first portion is greater than an aperture diameter of the second portion.

4. The electronic device according to claim 2, wherein the sealing assembly comprises a first sealing member, a light-transmitting member, and a fixing member, the first sealing member is clamped between the light-transmitting member and a slot bottom wall of the first portion, the fixing member is fixedly connected to a slot side wall of the first portion, and abuts against a surface of the light-transmitting member facing away from the first sealing member.

5. The electronic device according to claim 4, wherein the first sealing member is provided with a through-hole, the through-hole of the first sealing member extends through the first sealing member in a thickness direction of the first sealing member, at least a portion of the through-hole of the first sealing member is arranged opposite to the second portion, the light-transmitting member comprises a light-transmitting section, at least a portion of the light-transmitting section is arranged opposite to the through-hole, the fixing member is provided with a light-transmitting hole, the light-transmitting hole extends through the fixing member in a thickness direction of the fixing member, at least a portion of the light-transmitting hole is arranged opposite to the light-transmitting section and exposes the light-transmitting section, and the light-transmitting portion comprises the through-hole of the first sealing member, the light-transmitting section, and the light-transmitting hole.

6. The electronic device according to claim 5, wherein the light-transmitting hole is one of a hexagonal hole, a circular hole with a linear slot, a circular hole with a cross-shaped slot, or a circular hole with a fastening tool bayonet.

7. The electronic device according to claim 4, wherein the slot side wall of the first portion is provided with a first thread, an outer peripheral surface of the fixing member is provided with a second thread, and the second thread engages with the first thread.

8. The electronic device according to claim 4, wherein the sealing assembly further comprises a second sealing member, the second sealing member is clamped between the light-transmitting member and the fixing member, the second sealing member is provided with a through-hole, the through-hole of the second sealing member extends through the second sealing member in a thickness direction of the second sealing member, and at least a portion of the through-hole of the second sealing member is arranged opposite to the light-transmitting section and the light-transmitting hole, and exposes the light-transmitting section.

9. The electronic device according to claim 1, wherein the housing comprises a rear panel and a front panel that are oppositely arranged, the housing is provided with a liquid inlet and a liquid outlet, the liquid inlet and the liquid outlet are disposed in the rear panel and extend through the rear panel in a thickness direction of the rear panel, the front panel is provided with the mounting slot, and the mounting slot extends through the front panel in a thickness direction of the front panel.

10. The electronic device according to claim 1, wherein there are a plurality of mounting slots and indication modules, and each indication module is mounted in one of the mounting slots.

11. A liquid-cooled cabinet, comprising a cabinet body and at least one electronic device according to claim 1, and each electronic device is mounted on an inner side of the cabinet body.

12. The liquid-cooled cabinet according to claim 11, further comprising a main liquid inlet pipeline, a main liquid outlet pipeline, a plurality of liquid inlet pipes, and a plurality of liquid outlet pipes, wherein each liquid inlet pipe connects the main liquid inlet pipeline with a liquid inlet of the electronic device, and each liquid outlet pipe connects the main liquid outlet pipeline with a liquid outlet of the electronic device.

13. The liquid-cooled cabinet according to claim 12, further comprising a coolant distribution unit, wherein the coolant distribution unit is connected to the main liquid inlet pipeline and the main liquid outlet pipeline, and is configured to deliver a cooling medium to the main liquid inlet pipeline and receive the cooling medium delivered by the main liquid outlet pipeline.
